(19) United States
(12) Patent Application Publication
(10) Pub. No.: US 2025/0309075 A1
(43) Pub. Date: Oct. 2, 2025

(54) SEMICONDUCTOR DEVICE AND METHOD OF MANUFACTURING THE SAME

(71) Applicant: Samsung Electronics Co., Ltd., Suwon-si, Gyeonggi-do (KR)

(72) Inventors: Gabin LEE, Suwon-si (KR); Duckgyu KIM, Suwon-si (KR)

(21) Appl. No.: 18/894,604

(22) Filed: Sep. 24, 2024

(30) Foreign Application Priority Data
Mar. 27, 2024 (KR) 10-2024-0041828

(51) Int. Cl. H01L 23/498

(52) U.S. Cl. CPC H01L 23/49816

(57) ABSTRACT

A semiconductor package may include a substrate, a first pad on the substrate, and a first bump structure on the first pad, wherein the first bump structure includes a first conductive post structure on the first pad and connected to an upper surface of the first pad and a first solder bump connected to an upper surface of the first conductive post structure, and the first conductive post structure includes a first conductive portion and a first insulating pattern on a side surface of a lower portion of the first conductive portion, wherein a side surface of an upper portion of the first conductive portion is free of the first insulating pattern.

### CROSS-REFERENCE TO RELATED APPLICATIONS

This U.S. non-provisional patent application claims priority under 35 U.S.C. § 119 to Korean Patent Application No.10-2024-0041828, filed on Mar. 27, 2024, in the Korean Intellectual Property Office, the entire contents of which are hereby incorporated by reference.

### BACKGROUND OF THE INVENTION

The inventive concept relates to a semiconductor package and a method of manufacturing the same, and specifically, to a semiconductor package having a solder ball and a method of manufacturing the same.

Trends in the electronics industries are to fabricate lightweight, compact, high speed, multi-functional and high performance products at reasonable prices. A multi-chip stacked package technique or a system-in-package technique is used to meet these trends. As compared to a single chip semiconductor package, a multi-chip stacked package or a system-in-package may perform a number of functions corresponding to those of unit semiconductor devices. Although the multi-chip stacked package or the system-in-package may be somewhat thicker than a typical single chip package, they have a planar size similar to that of a single chip package and thus are primarily used for high-end, compact, and portable products such as mobile phones, laptop computers, memory cards, or portable camcorders.

Semiconductor packages typically include solder balls as electrical connection terminals or dummy terminals. Abnormalities in a shape of the solder ball may lead to a decrease in yield or process defects, and may lead to poor electrical characteristics of semiconductor devices. Therefore, it may be important to form solder balls without shape abnormalities when manufacturing semiconductor devices.

### SUMMARY

An object of the inventive concept is to provide a semiconductor package with improved structural and driving stability and a method of manufacturing the same.

An object of the inventive concept is to provide a method of manufacturing a semiconductor package with less defects and a semiconductor package manufactured through the method.

A semiconductor package according to some embodiments of the inventive concept may include a first pad on the substrate and a first bump structure on the first pad, wherein the first bump structure includes a first conductive post structure on the first pad and connected to an upper surface of the first pad and a first solder bump connected to an upper surface of the first conductive post structure, and the first conductive post structure includes a first conductive portion and a first insulating pattern on a side surface of a lower portion of the first conductive portion, wherein a side surface of an upper portion of the first conductive portion is free of the first insulating pattern.

A semiconductor package according to some embodiments of the inventive concept may include a substrate, a pad on the substrate, a passivation layer on the pad and on the substrate and having an opening exposing the pad, a conductive post structure on the passivation layer and connected to the pad through the opening, and a solder bump connected to an upper surface of the conductive post structure, wherein the conductive post structure includes a conductive post and an insulating pattern on a side surface of the conductive post, the solder bump contacts an upper surface of the conductive post and a portion of a side surface of the conductive post, and the insulating pattern is spaced apart from the solder bump.

A method of manufacturing a semiconductor package according to some embodiments of the inventive concept may include forming a pad on a substrate, forming a first photosensitive layer on the pad and on the substrate, performing a first photo process on the first photosensitive layer to form an insulating pattern on the pad, the insulating pattern extending in a direction perpendicular to an upper surface of the pad, and the insulating pattern having a first opening extending through the insulating pattern to the pad, forming a second photosensitive layer on the pad and on the insulating pattern on the substrate, performing a second photo process on the second photosensitive layer to form a sacrificial layer, the sacrificial layer having a second opening extending through the sacrificial layer to the first opening, filling the second opening with a conductive material to form a conductive post, removing the sacrificial layer, and providing a solder bump on the conductive post.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view illustrating a semiconductor package according to embodiments of the inventive concept.

FIG. 2 is a plan view for explaining a semiconductor package according to embodiments of the inventive concept, showing an enlarged portion of a portion of the semiconductor package.

FIGS. 3 to 6 are cross-sectional views for explaining semiconductor packages according to embodiments of the inventive concept.

FIGS. 7 and 8 are cross-sectional views for explaining semiconductor devices according to embodiments of the inventive concept.

FIG. 9 is a cross-sectional view for explaining a semiconductor package according to embodiments of the inventive concept.

FIG. 10 is a cross-sectional view for explaining a semiconductor device according to embodiments of the inventive concept.

FIGS. 11 to 22 are cross-sectional views for explaining a method of manufacturing a semiconductor package according to embodiments of the inventive concept.

### DETAILED DESCRIPTION

A semiconductor package according to the concept of the inventive concept will be described with reference to the drawings.

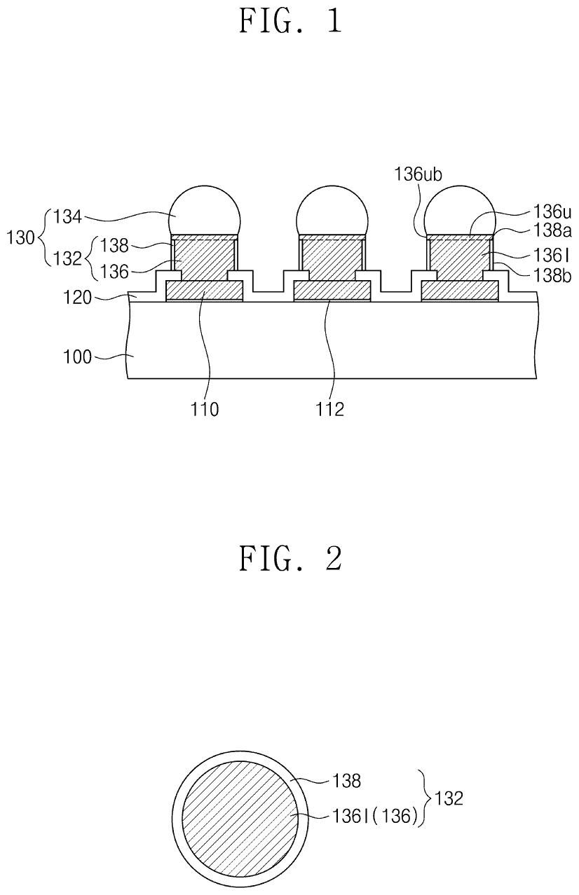

FIG. 1 is a cross-sectional view illustrating a semiconductor package according to embodiments of the inventive concept. FIG. 2 is a plan view for explaining a semiconductor package according to embodiments of the inventive concept, showing an enlarged portion of a conductive post structure of the semiconductor package.

Referring to FIGS. 1 and 2, a substrate 100 may be provided. The substrate 100 may include a semiconductor substrate. For example, the substrate 100 may be a semiconductor substrate such as a semiconductor wafer. When the substrate 100 is a semiconductor substrate, the substrate 100 may include a circuit directly therein. In detail, the substrate 100 may be a semiconductor chip including electronic devices such as transistors. For example, the substrate 100 may be a wafer level die formed of a semiconductor such as silicon (Si). The substrate 100 may be a bulk silicon substrate, a silicon-on-insulator (SOI) substrate, a germanium (Ge) substrate, a germanium-on-insulator (GOI) substrate, a silicon-germanium (Si—Ge) substrate, or a substrate of an epitaxial thin layer obtained by performing selective epitaxial growth (SEG). The substrate 100 may include, for example, at least one of silicon (Si), germanium (Ge), silicon germanium (SiGe), gallium arsenide (GaAs), indium gallium arsenide (InGaAs), aluminum gallium arsenide (AlGaAs), or a mixture thereof.

Alternatively, the substrate 100 may be a package substrate for mounting a semiconductor package on an external device, motherboard, or other substrate. Alternatively, the substrate 100 may be an interposer for redistributing semiconductor chips of a semiconductor package and connecting them to the package substrate of the semiconductor package. For example, the substrate 100 may be a printed circuit board (PCB) having a signal pattern or a redistribution substrate having a plurality of wiring layers.

The substrate 100 may have substrate pads 110 on an upper surface of the substrate 100. The substrate pads 110 may be spaced apart from each other. Heights of the substrate pads 110 may be substantially the same. For example, a distance from the upper surface of the substrate 100 to upper surfaces of the substrate pads 110 may all be the same. Widths of the substrate pads 110 may be the same. However, the inventive concept is not limited thereto, and the widths of the substrate pads 110 may be different. The substrate pads 110 may be electrically connected to wiring or circuitry in the substrate 100. A planar shape of the substrate pads 110 may be circular. Alternatively, the planar shape of the substrate pads 110 may have a polygonal shape, such as a square, or a line shape. The substrate pads 110 may include metal such as copper (Cu).

Seed layers may be between the substrate pads 110 and the substrate 100. For example, seed patterns 112 may be between the substrate 100 and the substrate pads 110. Each of the seed patterns 112 may be on one lower surface of the substrate pads 110. FIG. 1 shows that the seed patterns 112 are on only lower surfaces of the substrate pads 110, but the inventive concept is not limited thereto. The seed patterns 112 may extend from the lower surface of the substrate pads 110 onto side surfaces of the substrate pads 110. Hereinafter, description will continue based on the embodiment of FIG. 1. The seed patterns 112 may include a metal such as gold (Au).

A passivation layer 120 may be on the substrate 100. The passivation layer 120 may be on or cover the upper surface of the substrate 100. In this case, the passivation layer 120 may be on or cover the substrate pads 110. The passivation layer 120 may conformally cover the upper surface of the substrate 100 and the substrate pads 110. That is, the passivation layer 120 may be on the upper surface of the substrate 100 and extend on a sidewall and at least a portion of the upper surface of the substrate pads 110. The passivation layer 120 may include an insulating material. For example, the passivation layer 120 may include silicon oxide (SiO), silicon nitride (SiN), silicon oxynitride (SiON), silicon carbide nitride (SiCN), or a multilayer layer thereof. Alternatively, the passivation layer 120 may include a photosensitive material. For example, the passivation layer 120 may include a photo-imageable dielectric (PID) polymer. For example, the photo-imageable dielectric polymer may include at least one of photosensitive polyimide (PI), polybenzoxazole (PBO), phenol-based polymer, or benzocyclobutene-based polymer.

The passivation layer 120 may have openings that vertically penetrate or extend through the passivation layer 120. The openings may be positioned on substrate pads 110. Each of the openings may be on one of the substrate pads 110 and may expose or extend through to a portion of the upper surface of the substrate pads 110. That is, a planar shape and planar area of the openings may be smaller than the planar shape and planar area of the substrate pads 110. When viewed in a plan view, each of the openings may be inside one of the substrate pads 110. For example, the openings may expose or extend through to a center of each of the substrate pads 110, and the passivation layer 120 may be on or cover edges of each of the substrate pads 110. The planar shape of the openings may be circular. Alternatively, the planar shape of the openings may have a polygonal shape, such as a square or an octagon.

Bump structures 130 may be on the passivation layer 120. Each of the bump structures 130 may be on one of the substrate pads 110. The bump structures 130 may penetrate or extend through the passivation layer 120 and be connected to the substrate pads 110. For example, the bump structures 130 may be connected to the upper surfaces of the substrate pads 110 exposed by or accessible through the openings. A width of the bump structures 130 may be larger than the width of the openings. When viewed in a plan view, the openings may be inside the bump structures 130. The bump structures 130 may protrude onto the passivation layer 120. Accordingly, the bump structures 130 may completely fill the openings. A portion of the bump structures 130 may extend through the passivation layer 120. That is, the bump structures 130 may completely cover the openings, and the openings may be distinguished from the outside due to the bump structures 130. Each of the bump structures 130 may have a conductive post structure 132 and a solder bump 134 on the conductive post structure 132. Hereinafter, the configuration of the bump structures 130 will be described in more detail, based on one bump structure 130.

The conductive post structure 132 may have a pillar shape. The width of the conductive post structure 132 may be constant. Here, the width of the conductive post structure 132 may correspond to the width of the bump structures 130 described above. The conductive post structure 132 may be in contact with the substrate pads 110, may fill the openings of the passivation layer 120, and may protrude onto the passivation layer 120. That is, as shown in FIG. 1, the passivation layer 120 may have a shape that is inserted into a lower portion of the conductive post structure 132 on the substrate pad 110. The conductive post structure 132 may include a conductive post 136 and an insulating pattern 138.

The conductive post 136 may have a pillar shape. For example, the conductive post 136 may be connected to an upper surface of one of the substrate pads 110 and may extend vertically from the upper surface of one of the substrate pads 110. The conductive post 136 may be on a portion of the upper surface of the passivation layer 120. The conductive post 136 may be a conductive portion for electrical conduction in the conductive post structure 132. The conductive post 136 may include a metal material such as copper (Cu).

The insulating pattern 138 may be on an outer peripheral surface of the conductive post 136. In detail, the insulating pattern 138 may be on or cover an outer peripheral surface of a lower portion 136l of the conductive post 136 and expose an outer peripheral surface 136ub of an upper portion 136u of the conductive post 136. The upper portion 136u of the conductive post 136 may be free of the insulating pattern 138. That is, an upper surface 138a of the insulating pattern 138 may be lower than an upper surface of the conductive post 136. A height of the insulating pattern 138 may be 80% to 90% of a height of the conductive post 136. For example, a height of the upper portion 136u of the conductive post 136 may be 10% to 20% of a height of the conductive post 136. A thickness of the insulating pattern 138 may be 2% to 30% of a diameter of the conductive post structure 132. In this case, the thickness of the insulating pattern 138 may be defined as a distance from the outer peripheral surface of the lower portion 136l of the conductive post 136 to the outer peripheral surface 138b of the insulating pattern 138. The insulating pattern 138 may include an insulating material. A wettability between the insulating pattern 138 and a molten solder bump 134 may be lower than a wettability between the conductive post 136 and the molten solder bump 134. The insulating pattern 138 may include a photosensitive material. For example, the insulating pattern 138 may include a photo-imageable dielectric (PID) material. The insulating pattern 138 may include a negative type photosensitive material. The negative type photosensitive material refers to a material in which a portion that does not receive light during an exposure process is removed during a development process.

The upper portion 136u of the conductive post 136 may extend onto an upper surface 138a of the insulating pattern 138. That is, the upper portion 136u of the conductive post 136 may be on or cover both the lower portion 136l of the conductive post 136 and the insulating pattern 138. The outer peripheral surface 136ub of the upper portion 136u of the conductive post 136 may be coplanar with the outer peripheral surface 138b of the insulating pattern 138. The thickness of the insulating pattern 138 may be 2% to 30% of the diameter of the upper portion 136u of the conductive post 136.

Solder bumps 134 may be on the upper surface of the conductive post structure 132. The solder bump 134 may have a spherical, hemispherical, or partially cut spherical shape on the upper surface of the conductive post structure 132. However, the inventive concept is not limited thereto. The maximum width of the solder bump 134 may be greater than the width of the conductive post structure 132. The solder bump 134 may include a solder material or solder alloy containing tin (Sn) or the like.

According to embodiments of the inventive concept, the lower portion 136l of the conductive post 136 may be surrounded by an insulating pattern 138 having a low wettability with the molten solder bump 134. During a reflow process for mounting a semiconductor package, side wicking, in which the molten solder bump 134 flows and spreads to the lower portion 136l of the conductive post 136, may not occur. The molten solder bump 134 may move excessively on a side surface of the conductive post 136 and a bridge defect connected to another adjacent solder bump 134 may not occur. Delamination of the solder bump 134 capable of occurring when the molten solder bump 134 flows onto the passivation layer 120, defects due to an air gap, or defects due to a difference in thermal expansion coefficient may not occur. Thus, a method of manufacturing a semiconductor package with fewer defects may be provided, and a semiconductor package manufactured through this method with improved driving stability may be provided.

In addition, the insulating pattern 138 may expose the outer peripheral surface of the upper portion 136u of the conductive post 136. That is, the outer peripheral surface of the upper portion 136u of the conductive post 136 may be free of the insulating pattern 138. The molten solder bump 134 may be on both the upper surface and the outer peripheral surface of the upper portion 136u of the conductive post 136, and may form a connection terminal strongly coupled to the conductive post 136, after the reflow process of the solder bump 134.

In the following embodiments, for convenience of explanation, detailed descriptions of technical features overlapping with those previously described with reference to FIGS. 1 and 2 will be omitted, and differences will be described in detail. The same reference numerals may be provided for the same components as the semiconductor devices according to the embodiments of the inventive concept described above.

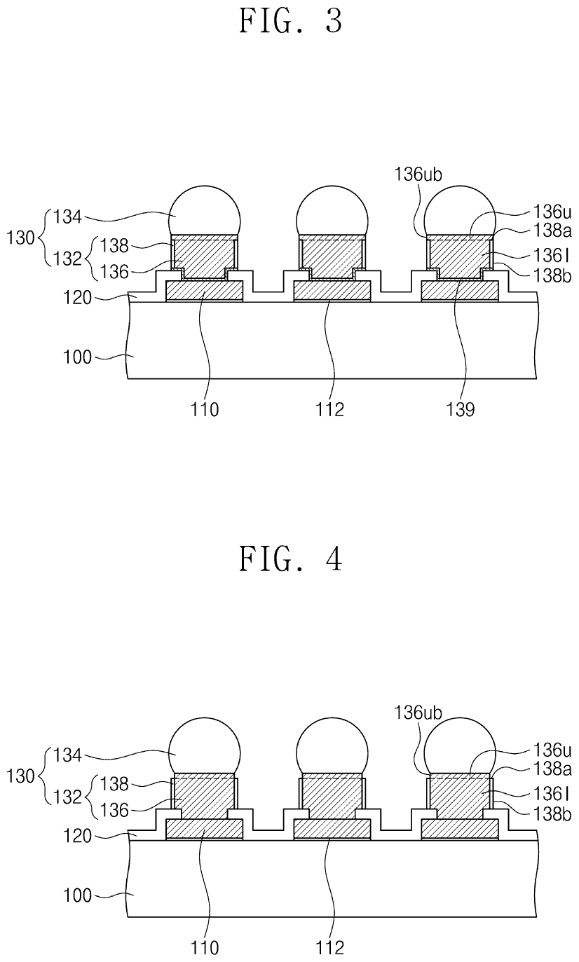

FIG. 3 is a cross-sectional view for explaining a semiconductor package according to embodiments of the inventive concept.

Referring to FIG. 3, each of conductive post structures 132 may further include a seed/barrier pattern 139. Hereinafter, the configuration of the bump structures 130 will be described in more detail, based on one bump structure 130.

A seed/barrier pattern 139 may be between the substrate pad 110 and the conductive post 136. The seed/barrier pattern 139 may be on the lower surface of the conductive post 136. In detail, the seed/barrier pattern 139 may conformally cover the lower portion 136l of the conductive post 136. The seed/barrier pattern 139 may extend from between the conductive post 136 and the substrate pad 110 to between the conductive post 136 and the passivation layer 120. The seed/barrier pattern 139 may extend from the lower surface of the conductive post 136 onto the lower surface of the insulating pattern 138. That is, the seed/barrier pattern 139 may be on both the lower surface of the conductive post 136 and the lower surface of the insulating pattern 138. A side surface of the seed/barrier pattern 139 may be coplanar with the outer peripheral surface 138b of the insulating pattern 138. The seed/barrier pattern 139 may serve as a seed layer to form the conductive post 136 during a manufacturing process of a semiconductor device, or may serve as a barrier layer that prevents components from diffusing between the conductive post 136 and the substrate pad 110 or between the conductive post 136 and the passivation layer 120. The seed/barrier pattern 139 may include only one of the seed layer and the barrier layer, or may be a multilayer layer including both the seed layer and the barrier layer. The seed layer may include gold (Au), silver (Ag), nickel (Ni), and tungsten (W). The barrier layer may include a metal nitride layer or a multilayer of a metal layer and a metal nitride layer. The metal nitride layer may include at least one of titanium nitride (TiN), tantalum nitride (TaN), tungsten nitride (WN), nickel nitride (NiN), cobalt nitride (CON), and platinum nitride (PtN).

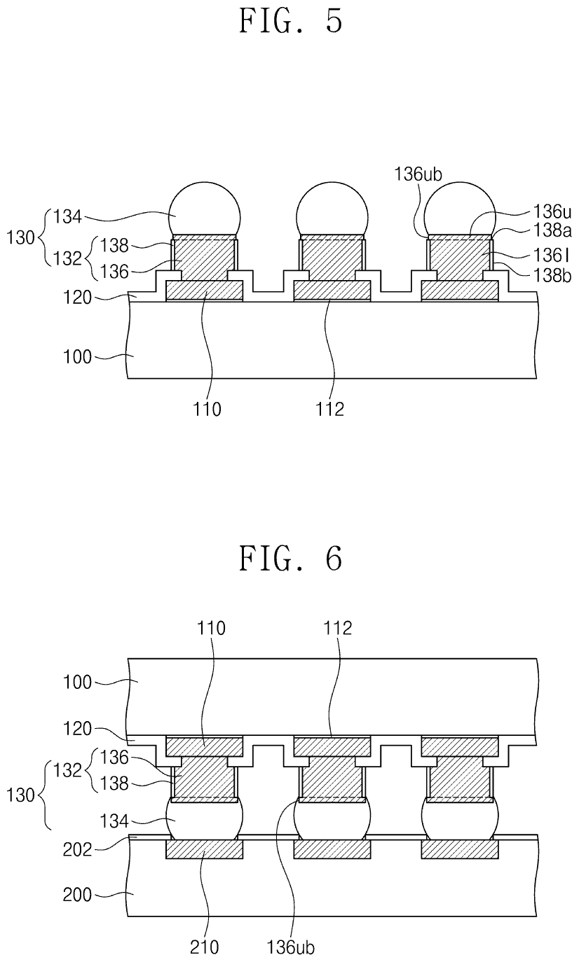

FIGS. 4 and 5 are cross-sectional views for explaining a semiconductor package according to embodiments of the inventive concept.

FIG. 1 shows that the upper portion 136u of the conductive post 136 extends onto the upper surface 138a of the insulating pattern 128, but the inventive concept is not limited thereto.

Referring to FIG. 4, the upper portion 136u of the conductive post 136 may not cover or be on the upper surface 138a of the insulating pattern 138. The width or diameter of the upper portion 136u of the conductive post 136 may be the same as the width or diameter of the lower portion 136l of the conductive post 136. The outer peripheral surface 136ub of the upper portion 136u of the conductive post 136 may be coplanar with the outer peripheral surface of the lower portion 136l. For example, the conductive post 136 may have a pillar shape with a constant diameter or width. The insulating pattern 138 may expose the outer peripheral surface 136ub of the upper portion 136u of the conductive post 136. That is, the outer peripheral surface 136ub of the upper portion 136u of the conductive post 136 may be free of the insulating pattern 138. The upper portion 136u of the conductive post 136 may expose the upper surface 138a of the insulating pattern 138. The upper surface 138a of the insulating pattern 138 may not be in contact with the upper portion 136u of the conductive post 136. The outer peripheral surface 138ub of the upper portion 136u of the conductive post 136 and the outer peripheral surface 138b of the insulating pattern 138 may be stepped.

Alternatively, the upper portion 136u of the conductive post 136 may be on a portion of the upper surface 138a of the insulating pattern 138 and expose the remaining portion thereof.

Referring to FIG. 5, the upper portion 136u of the conductive post 136 may extend onto the upper surface 138a of the insulating pattern 138. In this case, the upper portion 136u of the conductive post 136 may be spaced apart from the outer peripheral surface 138b of the insulating pattern 138. The outer peripheral surface 136ub of the upper portion 136u of the conductive post 136 may be on the upper surface 138a of the insulating pattern 138. The outer peripheral surface 138ub of the upper portion 136u of the conductive post 136 and the outer peripheral surface 138b of the insulating pattern 138 may be stepped.

FIG. 6 is a cross-sectional view for explaining a semiconductor package according to embodiments of the inventive concept.

Referring to FIG. 6, a first substrate 100 may be provided. The first substrate 100 may be a wiring substrate, a semiconductor substrate provided with a semiconductor element, or a semiconductor chip. The first substrate 100 may correspond to the substrate 100 described with reference to FIGS. 1 to 5. First substrate pads 110 may be on the first substrate 100. A first passivation layer 120 may be on the first substrate 100 and on the first substrate pads 110. The first passivation layer 120 may have openings exposing the first substrate pads 110. Bump structures 130 may be on the first substrate pads 110. Each of the bump structures 130 may have a conductive post structure 132 and a solder bump 134 on the conductive post structure 132. The conductive post structure 132 may have a conductive post 136 and an insulating pattern 138 surrounding a pillar portion of the conductive post 136. Here, the pillar portion of the conductive post 136 may correspond to the lower portion 136l of the conductive post 136 described with reference to FIGS. 1 to 5. The first substrate pads 110, the first passivation layer 120, and the bump structures 130 may correspond to the substrate pads 110, the passivation layer 120, and the bump structures 130 described with reference to FIGS. 1 to 5.

A second substrate 200 may be provided. The second substrate 200 may be a wiring substrate, a semiconductor substrate provided with a semiconductor element, or a semiconductor chip. Second substrate pads 210 may be on an upper surface of the second substrate 200. The second substrate pads 210 may be at positions corresponding to the first substrate pads 110. A second passivation layer 202 may be on the upper surface of the second substrate 200. The second passivation layer 202 may have openings exposing the second substrate pads 210.

The first substrate 100 may be on the second substrate 200. In this case, the first substrate pads 110, the first passivation layer 120, and the bump structures 130 may be on a lower surface of the first substrate 100 facing the second substrate 200. The bump structures 130 may face the second substrate pads 210.

Solder bumps 134 may be connected to the second substrate pads 210. The solder bumps 134 may connect the second substrate pads 210 and the conductive post structures 132. In this case, some of the solder bumps 134 may extend onto the outer peripheral surface 136ub of the head portion of the conductive post 136 of the conductive post structures 132. Here, a head portion of the conductive post 136 may correspond to the upper portion 136u of the conductive post 136 described with reference to FIGS. 1 to 5. The solder bumps 134 may partially cover and be on the outer peripheral surface 136ub of the head portion of the conductive post 136 of the conductive post structures 132. The solder bumps 134 may be spaced apart from the insulating patterns 138 of the conductive post structures 132. For example, the solder bumps 134 extend onto sides of the conductive post structures 132, but may only be on the head portion of the conductive post 136.

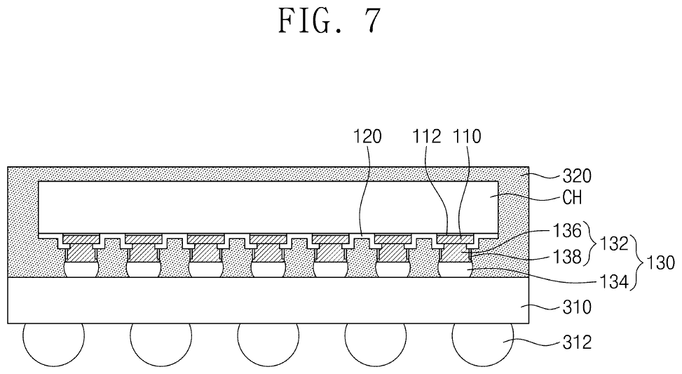

FIG. 7 is a cross-sectional view illustrating a semiconductor device according to embodiments of the inventive concept.

Referring to FIG. 7, a package substrate 310 may be provided. The package substrate 310 may include a printed circuit board (PCB) or a redistribution substrate. Although not shown, the package substrate 310 may include connection pads on an upper surface of the package substrate 310 and external pads on a lower surface of the package substrate 310. External terminals 312 may be on the external pads.

A semiconductor chip CH may be provided on the package substrate 310. The semiconductor chip CH may correspond to an element that includes the substrate 100, substrate pads 110, passivation layer 120, and bump structures 130 described with reference to FIGS. 1 to 5. As an example, the semiconductor chip CH may have a semiconductor substrate and integrated circuits formed on the semiconductor substrate. The semiconductor chip CH may have substrate pads 110, a passivation layer 120, and bump structures 130. The substrate pads 110 may be on an active surface of the semiconductor substrate. The passivation layer 120 may be on the substrate pads 110 on the active surface of the semiconductor substrate. The passivation layer 120 may have openings that expose or extend to the substrate pads 110. The bump structures 130 may be on the substrate pads 110. Each of the bump structures 130 may have a conductive post structure 132 and a solder bump 134 on the conductive post structure 132. The conductive post structure 132 may have a conductive post 136 and an insulating pattern 138 surrounding a pillar portion of the conductive post 136. Here, the pillar portion of the conductive post 136 may correspond to the lower portion 136l of the conductive post 136 described with reference to FIGS. 1 to 5.

The semiconductor chip CH may be mounted on the package substrate 310 using a flip chip bonding manner. The semiconductor chip CH may be aligned so that the bump structures 130 face the upper surface of the package substrate 310, and the bump structures 130 may be connected to the connection pads of the package substrate 310. In detail, the semiconductor chip CH may be mounted on the package substrate 310 by soldering the solder bumps 134 included in the bump structures 130 to the connection pads. In this case, some of the solder bumps 134 may extend onto the outer peripheral surface of the head portion of the conductive post 136 of the conductive post structures 132. Here, a head portion of the conductive post 136 may correspond to the upper portion 136u of the conductive post 136 described with reference to FIGS. 1 to 5. The solder bumps 134 may be spaced apart from the insulating patterns 138 of the conductive post structures 132.

A molding layer 320 on the semiconductor chip CH may be on the upper surface of the package substrate 310. The molding layer 320 may include, for example, an epoxy molding compound (EMC). According to some embodiments, an underfill layer (not shown) may be further provided between the semiconductor chip CH and the package substrate 310.

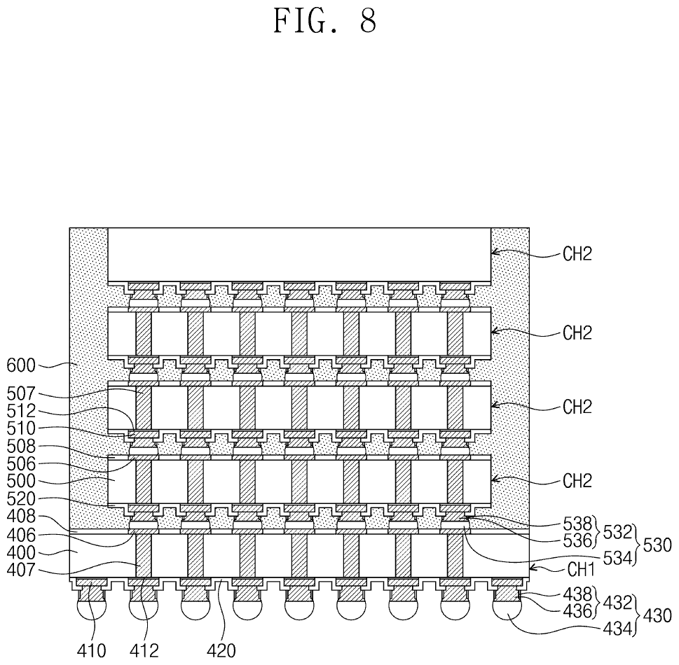

FIG. 8 is a cross-sectional view for explaining a semiconductor device according to embodiments of the inventive concept.

Referring to FIG. 8, a first semiconductor chip CHI may be provided. The first semiconductor chip CHI may correspond to an element that includes the substrate 100, substrate pads 110, passivation layer 120, and bump structures 130 described with reference to FIGS. 1 to 5. The first semiconductor chip CHI may include a first semiconductor substrate 400, an integrated circuit and wiring layer formed on the first semiconductor substrate 400, first lower pads 410 on a lower surface of the first semiconductor substrate 400, a first lower passivation layer 420 covering or on the first lower pads 410 on the lower surface of the first semiconductor substrate 400, first upper pads 406 on an upper surface of the first semiconductor substrate 400, a first upper passivation layer 408 on the first upper pads 406 on the upper surface of the first semiconductor substrate 400, and first through vias 407 vertically penetrating or extending through the first semiconductor substrate 400 and connecting the first lower pads 410 to the first upper pads 406 or connecting the integrated circuit to the first upper pads 406. First bump structures 430 may be connected to the first lower pads 410. The first semiconductor substrate 400, the first lower pads 410, the first lower passivation layer 420, and the first bump structures 430 may correspond to the substate 100, the substate pads 110, the passivation layer 120, and the bump structures 130 described with reference to FIGS. 1 to 5. Each of the first bump structures 430 may have a first conductive post structure 432 and a first solder bump 434 on the first conductive post structure 432. The first conductive post structure 432 may have a first conductive post 436 and a first insulating pattern 438 surrounding a pillar portion of the first conductive post 436. Here, the pillar portion of the first conductive post 436 may correspond to the lower portion 136l of the conductive post 136 described with reference to FIGS. 1 to 5. Moreover, the first conductive post 436 may be a first conductive portion for electrical conduction in the first conductive post structure 432. According to other embodiments, a wiring substrate may be provided in place of the first semiconductor chip CH1.

A chip stack may be on the first semiconductor chip CH1. The chip stack may include at least one second semiconductor chip CH2 stacked on the first semiconductor chip CH1. Each of the second semiconductor chips CH2 may be a memory chip such as DRAM, SRAM, MRAM, or flash memory. Alternatively, each of the second semiconductor chips CH2 may be a logic chip. A width of the second semiconductor chips CH2 may be smaller than a width of the first semiconductor chip CH1. FIG. 8 shows that one chip stack is provided, but the inventive concept is not limited thereto. When a plurality of chip stacks are provided, the chip stacks may be spaced apart from each other on the first semiconductor chip CH1. Hereinafter, the second semiconductor chips CH2 will be described based on the lowermost second semiconductor chip CH2.

The second semiconductor chip CH2 may correspond to an element that includes the substrate 100, the passivation layer 120, and the substrate pads 110 described with reference to FIGS. 1 to 8. The second semiconductor chip CH2 may include a second semiconductor substrate 500, an integrated circuit and wiring layer formed on the second semiconductor substrate 500, second lower pads 510 on a lower surface of the second semiconductor substrate 500, a second lower passivation layer 520 on the second lower pads 510 on the lower surface of the second semiconductor substrate 500, second upper pads 506 on an upper surface of the second semiconductor substrate 500, a second upper passivation layer 508 surrounding the second upper pads 506 on the upper surface of the second semiconductor substrate 500, and second through vias 507 vertically penetrating or extending through the second semiconductor substrate 500 and connecting the second lower pads 510 to the second upper pads 506 or connecting the integrated circuit to the second upper pads 506. Second bump structures 530 may be connected to the second lower pads 510. The second semiconductor substrate 500, the second lower pads 510, the second lower passivation layer 520, and the second bump structures 530 may correspond to the substrate 100, the substrate pads 110, the passivation layer 120, and the bump structures 130 described with reference to FIGS. 1 to 5. Each of the second bump structures 530 may have a second conductive post structure 532 and a second solder bump 534 on the second conductive post structure 532. The second conductive post structure 532 may have a second conductive post 536 and a second insulating pattern 538 surrounding a pillar portion of the second conductive post 536. Here, the pillar portion of the second conductive post 536 may correspond to the lower portion 136l of the conductive post 136 described with reference to FIGS. 1 to 5. Moreover, the second conductive post 536 may be a second conductive portion for electrical conduction in the second conductive post structure 532.

The second semiconductor substrate 500 may include a semiconductor material. For example, the second semiconductor substrate 500 may be a silicon (Si) single crystal substrate. A lower surface of the second semiconductor substrate 500 may be an active surface, and an upper surface of the second semiconductor substrate 500 may be an inactive surface.

An integrated circuit may be on the lower surface of the second semiconductor substrate 500. For example, the integrated circuit may be a memory circuit. For example, the second semiconductor chip CH2 may be a memory chip. Alternatively, the integrated circuit may be a logic circuit. The integrated circuit may include electronic devices such as transistors, insulation patterns, and wiring patterns.

The second semiconductor chips CH2 may be substantially identical to each other. However, the uppermost second semiconductor chip CH2 may not include the second through vias 507, the second upper pads 506, and the second upper passivation layer 508, unlike the remaining second semiconductor chips CH2. Additionally, a thickness of the uppermost second semiconductor chip CH2 may be greater than that of the remaining second semiconductor chips CH2.

The second semiconductor chips CH2 may be electrically connected to each other. For example, the second bump structures 530 of the second semiconductor chips CH2 may be connected to the second upper pads 506 of another second semiconductor chip CH2 positioned therebelow.

The second solder bumps 534 may connect the second upper pads 506 and the second conductive post structures 532. In this case, a portion of the second solder bumps 534 may extend onto an outer peripheral surface of a head portion of the second conductive post 536 of the second conductive post structures 532. The second solder bumps 534 may be spaced apart from the second insulating pattern 538 of the second conductive post structures 532.

The chip stack may be mounted on the first semiconductor chip CH1. The chip stack may be on the first semiconductor chip CH1. The first upper pads 406 of the first semiconductor chip CH1 and the second bump structures 530 of the lowermost second semiconductor chip CH2 of the chip stack may be vertically aligned. The second bump structures 530 may be connected to the first upper pads 406. The second solder bumps 534 may connect the first upper pads 406 and the second conductive post structures 532.

Although not shown, an underfill layer may be between the second semiconductor chips CH2 and between the lowermost second semiconductor chip CH2 and the first semiconductor chip CH1. The underfill layer may fill the space between the second semiconductor chips CH2 and a space between the lowermost second semiconductor chip CH2 and the first semiconductor chip CH1. The underfill layer may surround the second bump structures 530.

The package molding layer 600 may surround the second semiconductor chips CH2 on the first semiconductor chip CH1. The molding layer 600 may protect the second semiconductor chips CH2. The molding layer 600 may include an insulating material. For example, the molding layer 600 may include epoxy molding compound (EMC).

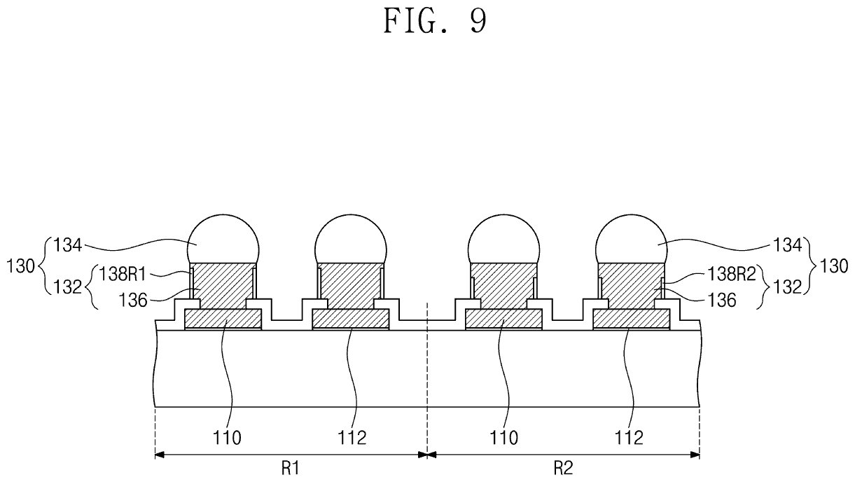

FIG. 9 is a cross-sectional view for explaining a semiconductor package according to embodiments of the inventive concept.

Referring to FIG. 9, a substrate 100 may have a first region R1 and a second region R2. The first region R1 and the second region R2 may be distinct regions that do not overlap each other. FIG. 9 shows that the first region R1 and the second region R2 are in contact with each other, but the inventive concept is not limited thereto. The first region R1 and the second region R2 may be spaced apart from each other. Hereinafter, the description will continue based on the embodiment of FIG. 9. The first region R1 and the second region R2 may be regions defined depending on a shape of the substrate 100. For example, the second region R2 may be at a center of the substrate 100, and the first region R1 may be at an edge of the substrate 100. That is, the second region R2 may be a central region of the substrate 100, and the first region R1 may be a peripheral region surrounding the second region R2.

Substrate pads 110 may be on an upper surface of the substrate 100. A passivation layer 120 on the substrate pads 110 may be on the upper surface of the substrate 100. The passivation layer 120 may have openings that expose the substrate pads 110. The openings may extend through the passivation layer 120.

Bump structures 130 may be on the substrate pads 110. Each of the bump structures 130 may have a conductive post structure 132 and a solder bump 134 on the conductive post structure 132. The conductive post structure 132 may have a conductive post 136 and an insulating pattern 138 surrounding a lower portion of the conductive post 136. The first substrate pads 110, the first passivation layer 120, and the bump structures 130 may correspond to the substrate pads 110, the passivation layer 120, and the bump structures 130 described with reference to FIGS. 1 to 5.

An insulating pattern 138R1 of the bump structures 130 on the first region RI and an insulating pattern 138R2 of the bump structures 130 on the second region R2 may have different shapes. For example, a height of the insulating pattern 138R1 on the first region R1 may be greater than a height of the insulating pattern 138R2 on the second region R2. An upper surface of the insulating pattern 138R1 in the first region R1 may be at a higher level from the substrate 100 than an upper surface of the insulating pattern 138R2 in the second region R2. A height of a lower portion of the conductive post 136 in the first region RI may be greater than a height of the conductive post 136 in the second region R2. The height of the upper portion of the conductive post 136 in the first region R1 may be lower than the height of the upper portion of the conductive post 136 in the second region R2. Upper surfaces of the conductive posts 136 may be at the same level in the first region R1 and the second region R2.

According to embodiments of the inventive concept, during a reflow process for mounting a semiconductor package, molten solder bumps 134 may be on the upper surface and outer peripheral surface of the conductive posts 136. Heights of the upper portions of the conductive posts 136 may be provided differently in the first region R1 and the second region R2, and thus the amount of molten solder bumps 134 flowing on the upper outer peripheral surface of the conductive posts 136 in the second region R2 may be greater that the amount of molten solder bumps 134 flowing on the upper outer peripheral surface of the conductive posts 136 in the first region R1. That is, during the reflow process, the amount of solder bumps 134 remaining on the upper surface of the conductive posts 136 may be variously changed depending on the position of the substrate 100, and accordingly, warpage of the substrate 100 may be improved. Accordingly, even when the substrate 100 is bent or there is a height distribution of pads on another substrate or an element on which the substrate 100 is mounted, there is a contact defect in which the bump structures 130 are not connected to the pads may not occur. That is, a semiconductor package with good electrical connection characteristics and improved driving stability may be provided.

FIG. 10 is a cross-sectional view for explaining a semiconductor package according to embodiments of the inventive concept.

Referring to FIG. 10, a first substrate 100 may be provided. The first substrate 100 may be a wiring substrate, a semiconductor substrate provided with a semiconductor element, or a semiconductor chip. The first substrate 100 may correspond to the substrate 100 described with reference to FIG. 9. The first substrate 100 may have a first region R1 and a second region R2. The second region R2 may be a central region of the substrate 100, and the first region R1 may be a peripheral region surrounding the second region R2. First substrate pads 110 may be on the first substrate 100. A first passivation layer 120 may be on the first substrate 100 and on the first substrate pads 110. The first passivation layer 120 may have openings exposing the first substrate pads 110. Bump structures 130 may be on the first substrate pads 110. Each of the bump structures 130 may include a conductive post structure 132 and a solder bump 134 on the conductive post structure 132. The conductive post structure 132 may have a conductive post 136 and an insulating pattern 138R1 or 138R2 surrounding a pillar portion of the conductive post 136. Here, the pillar portion of the conductive post 136 may correspond to the lower portion of the conductive post 136 described with reference to FIG. 9. The first substrate pads 110, the first passivation layer 120, and the bump structures 130 may correspond to the substrate pads 110, the passivation layer 120, and the bump structures 130 described with reference to FIG. 9. A height of the insulating pattern 138R1 on the first region R1 may be higher than a height of the insulating pattern 138R2 on the second region R2.

A second substrate 200 may be provided. The second substrate 200 may be a wiring substrate, a semiconductor substrate provided with a semiconductor element, or a semiconductor chip. Second substrate pads 210 may be on an upper surface of the second substrate 200. The second substrate pads 210 may be at positions corresponding to the first substrate pads 110. A second passivation layer 202 may be on the upper surface of the second substrate 200. The second passivation layer 202 may have openings exposing the second substrate pads 210.

The first substrate 100 may be on the second substrate 200. In this case, the first substrate pads 110, the first passivation layer 120, and the bump structures 130 may be on a lower surface of the first substrate 100 toward the second substrate 200. The bump structures 130 may face the second substrate pads 210.

Warpage of the first substrate 100 may occur due to heat generated when mounting the first substrate 100 on the second substrate 200. For example, as shown in FIG. 10, the first substrate 100 may be bent into a U-shaped smile type. In detail, the first substrate 100 may have a shape in which the second region R2, which is a central region of the first substrate 100, has a protruding (or convex) shape compared to the first region R1, which is an edge region of the first substrate 100. When viewed in a cross-sectional view, the second region R2 of the first substrate 100 may be at a lower level than the first region R1.

Solder bumps 134 may be connected to the second substrate pads 210. The solder bumps 134 may connect the second substrate pads 210 and the conductive post structures 132. In this case, some of the solder bumps 134 may extend onto an outer peripheral surface of a head portion of the conductive post 136 of the conductive post structures 132. Here, the head portion of the conductive post 136 may correspond to the upper portion of the conductive post 136 described with reference to FIG. 9. The solder bumps 134 may partially cover or be on at least a portion of the outer peripheral surface of the head portion of the conductive post 136 of the conductive post structures 132. The solder bumps 134 may be spaced apart from the insulating patterns 138 of the conductive post structures 132. The insulating patterns 138R1 and 138R2 may be provided at different heights in the first region R1 and the second region R2, and thus the amount of molten solder bumps 134 flowing on the outer peripheral surface of the head portion of the conductive posts 136 in the second region R2 may be greater than the amount of molten solder bumps 134 flowing on the outer peripheral surface of the head portions of the conductive posts 136 in the first region R1. A height of the solder bump 134 on the second region R2 may be smaller than a height of the solder bump 134 on the first region R1. Accordingly, the lowermost ends of the solder bumps 134 in the first region R1 and the second region R2 may be at the same or similar level. That is, heights of the insulating patterns 138R1 and 138R2 may be adjusted to improve the warpage of the first substrate 100 so that lowermost ends of the solder bump 134 may be positioned at the same level.

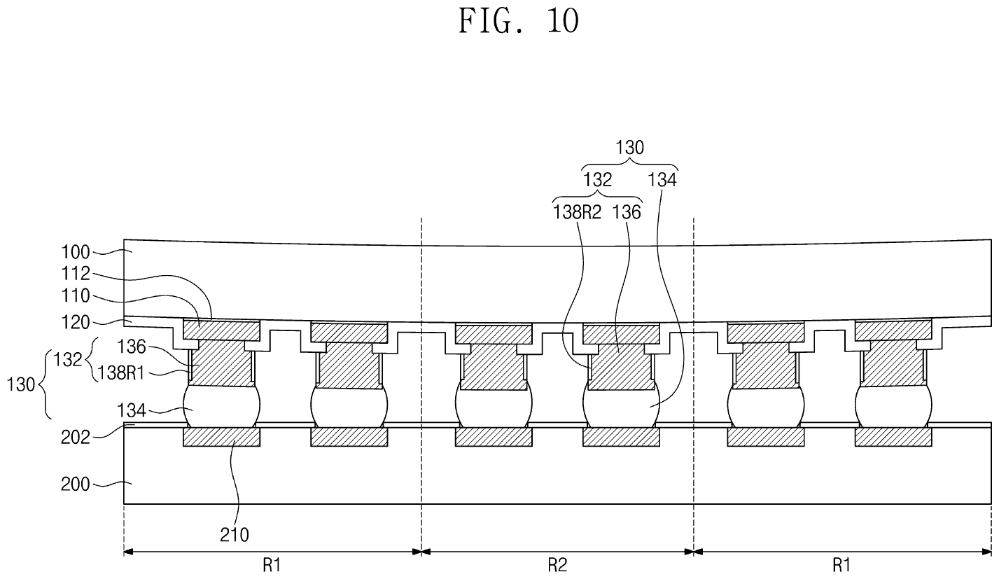

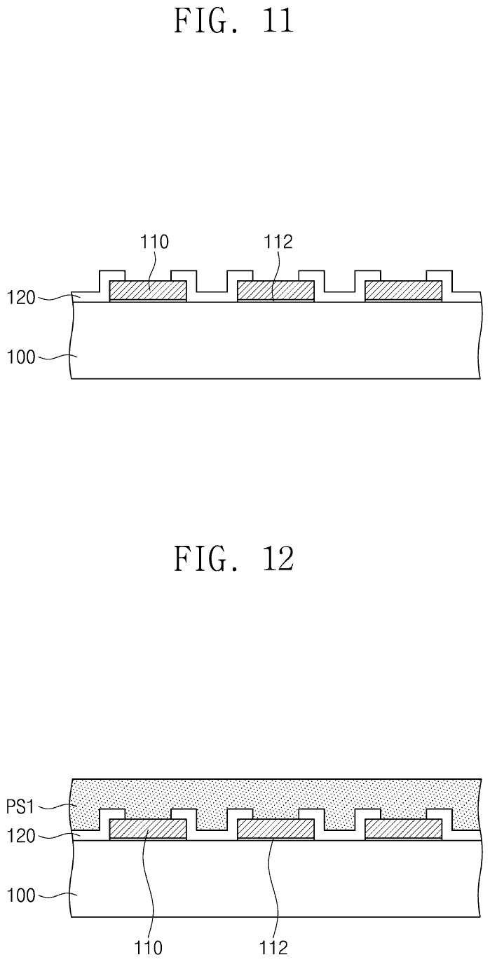

FIGS. 11 to 22 are cross-sectional views for explaining a method of manufacturing a semiconductor package according to embodiments of the inventive concept.

Referring to FIG. 11, a substrate 100 may be provided. The substrate 100 may include a semiconductor substrate. For example, the substrate 100 may be a semiconductor substrate such as a semiconductor wafer. A memory circuit, a logic circuit, or a combination thereof may be formed on the substrate 100. When the substrate 100 is a semiconductor substrate, the substrate 100 may include an integrated circuit therein. In detail, the substrate 100 may be a semiconductor chip including an electronic element such as a transistor.

Although not shown, the substrate 100 may further include insulating layers on the integrated circuit and a wiring layer including wiring patterns connected to the integrated circuit in the insulating layers.

Alternatively, the substrate 100 may be a package substrate for mounting a semiconductor package on an external device, motherboard, or other substrate. Alternatively, the substrate 100 may be an interposer for redistributing semiconductor chips of a semiconductor package and connecting them to the package substrate of the semiconductor package.

Substrate pads 110 may be formed on the substrate 100. For example, a seed layer may be formed on the substrate 100, and a mask pattern may be formed on the seed layer. The mask pattern may have openings defining regions where the substrate pads 110 are formed. The substrate pads 110 may be formed on the seed layer by performing a plating process. The plating process may be performed using the seed layer exposed by the mask pattern as a seed. The mask pattern may be removed. A portion of the seed layer exposed by removing the mask pattern may be removed to form seed patterns 112 below the substrate pads 110. Alternatively, for example, a mask pattern may be formed on the substrate 100. The mask pattern may have openings defining regions where the seed patterns 112 and the substrate pads 110 are formed. A seed layer may be formed to conformally cover or be on the upper surface of the mask pattern, inner walls, and bottom surfaces of the openings. A conductive layer may be formed by performing a plating process using the seed layer as a seed. By removing a portion of the conductive layer and a portion of the seed layer on the upper surface of the mask pattern, the substrate pads 110 and seed patterns 112 that remain in the opening may be formed. Afterwards, the mask pattern may be removed.

A passivation layer 120 may be formed on the substrate 100. For example, an insulating layer on the seed patterns 112 and the substrate pads 110 may be formed on the substrate 100. The insulating layer may be patterned to form the passivation layer 120 having openings exposing upper surfaces of the substrate pads 110.

Referring to FIG. 12, a first photosensitive layer PS1 may be formed on the passivation layer 120. The first photosensitive layer PS1 may be on the entire passivation layer 120 and the substrate pads 110. A thickness of the first photosensitive layer PS1 may be the same as a height of an insulating pattern 138 (refer to FIG. 20) of a conductive post structure 132 (refer to FIG. 20) to be formed later. For example, the thickness of the first photosensitive layer PS1 may be 80% to 90% of a height of the conductive post structure 132 to be formed. In this case, the thickness of the first photosensitive layer PS1 may mean a distance from an upper surface of the substrate pads 110 to an upper surface of the first photosensitive layer PS1. The first photosensitive layer PS1 may include a photosensitive material. For example, the first photosensitive layer PS1 may include a photo-imageable dielectric (PID). The first photosensitive layer PS1 may include a negative type photosensitive material.

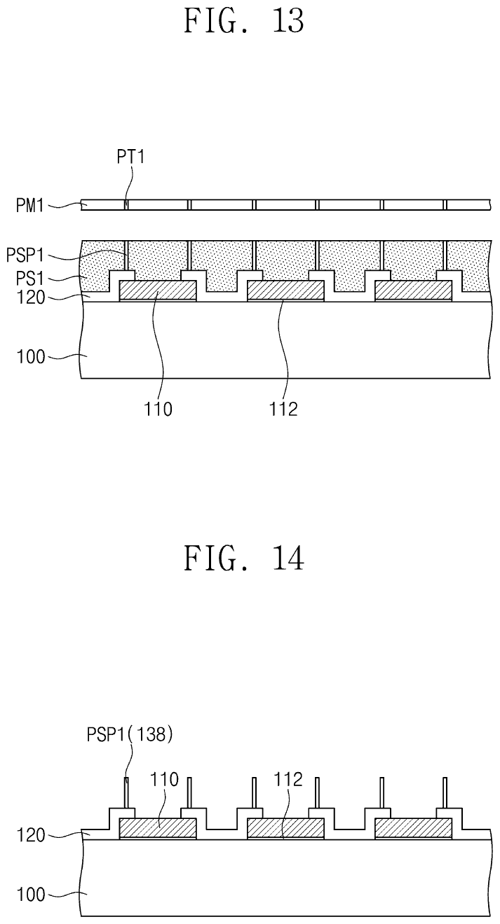

Referring to FIG. 13, a first photo process may be performed on the first photosensitive layer PS1. In detail, a first photo mask PM1 may be on the first photosensitive layer PS1. The first photo mask PM1 may have a first photo pattern PT1. The first photo pattern PT1 may correspond to the first photosensitive patterns PSP1 formed on the first photosensitive layer PS1. The first photo pattern PT1 may have ring-shaped patterns above the substrate pads 110. In detail, each of the patterns of the first photo pattern PT1 may have a ring shape surrounding the openings of the passivation layer 120 on the substrate pads 110. The first photo process may be performed using the first photo mask PM1. For example, light irradiated to the first photo mask PM1 may pass through the first photo pattern PT1 and be irradiated to the first photosensitive layer PS1, and physical characteristics of a portion of the first photosensitive layer PS1 irradiated with the light may change. The portion of the first photosensitive layer PSI to which the light is irradiated is defined as first photosensitive patterns PSP1.

Referring to FIG. 14, the remaining portions of the first photosensitive layer PS1 excluding the first photosensitive patterns PSP1 may be removed. Accordingly, the first photosensitive patterns PSP1 may remain. The first photosensitive patterns PSP1 may have a ring shape surrounding the openings of the passivation layer 120 when viewed in a plan view. The first photosensitive patterns PSP1 may have a hollow cylinder shape or a pipe shape extending in a direction perpendicular to an upper surface of the substrate pads 110. For example, the first photosensitive pattern PSP1 may have an opening that vertically penetrates or extends into the first photosensitive pattern PSP1 to the substrate pads 110 such that at least a portion of the substrate pads 110 is exposed. A thickness of the first photosensitive patterns PSP1 may be 2% to 30% of a diameter of the first photosensitive patterns PSP1. Here, the diameter of the first photosensitive patterns PSP1 corresponds to the diameter of a circle defined depending on the outer peripheral surface of the first photosensitive patterns PSP1, and the thickness of the first photosensitive patterns PSP1 corresponds to a distance between the outer peripheral surface and the internal surface of the first photosensitive patterns PSP1. The first photosensitive patterns PSP1 may correspond to the insulating patterns 138 (refer to FIG. 20) of the conductive post structures 132 (refer to FIG. 20) formed in a process to be described later.

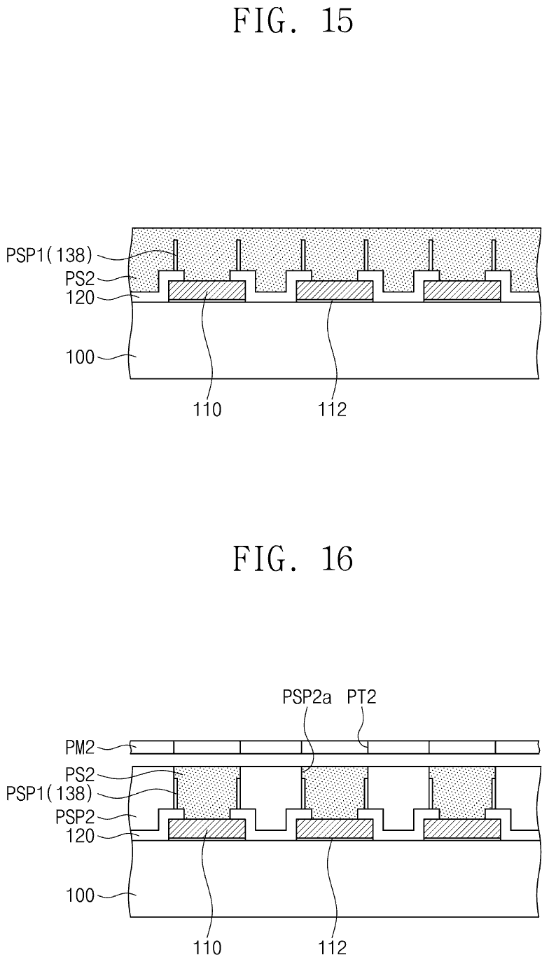

Referring to FIG. 15, a second photosensitive layer PS2 may be formed on the passivation layer 120. The second photosensitive layer PS2 may be on the entire passivation layer 120, the substrate pads 110, and the first photosensitive patterns PSP1. A thickness of the second photosensitive layer PS2 may be greater than a height of a conductive post structure 132 (refer to FIG. 20) to be formed later. Here, the thickness of the second photosensitive layer PS2 may mean a distance from an upper surface of the substrate pads 110 to an upper surface of the second photosensitive layer PS2. The second photosensitive layer PS2 may include a different material from the first photosensitive layer PS1. The second photosensitive layer PS2 may include a photosensitive material. For example, the second photosensitive layer PS2 may include a photo- imageable dielectric (PID). The second photosensitive layer PS2 may include a positive type photosensitive material. The positive type photosensitive material refers to a material in which the portion that receives light during the exposure process is removed during a development process.

Referring to FIG. 16, a second photo process may be performed on the second photosensitive layer PS2. In detail, a second photo mask PM2 may be on the second photosensitive layer PS2. The second photo mask PM2 may have a second photo pattern PT2. The second photo pattern PT2 may correspond to the second photosensitive patterns PSP2 formed on the second photosensitive layer PS2. The second photo pattern PT2 may have patterns that surround the first photosensitive patterns PSP1. The second photo process may be performed using the second photo mask PM2. For example, light irradiated to the second photo mask PM2 may pass through the second photo pattern PT2 and be irradiated to the second photosensitive layer PS2 inside the first photosensitive patterns PSP1, and physical characteristics of a portion of the second photosensitive layer PS2 irradiated with the light may change. The portion of the second photosensitive layer PS2 to which the light is irradiated may define a region where conductive posts 136 are formed in a process to be described later. A portion of the second photosensitive layer PS2 that is not irradiated with light is defined as a second photosensitive pattern PSP2.

A side surface of the portion of the second photosensitive layer PS2 to which the light is irradiated may be aligned with the outer peripheral surface of the first photosensitive patterns PSP1. That is, an interface between the portion of the second photosensitive layer PS2 to which the light is irradiated and the second photosensitive pattern PSP2 may be coplanar with the outer peripheral surface of the first photosensitive patterns PSP1. In this case, the semiconductor package described with reference to FIG. 1 may be manufactured.

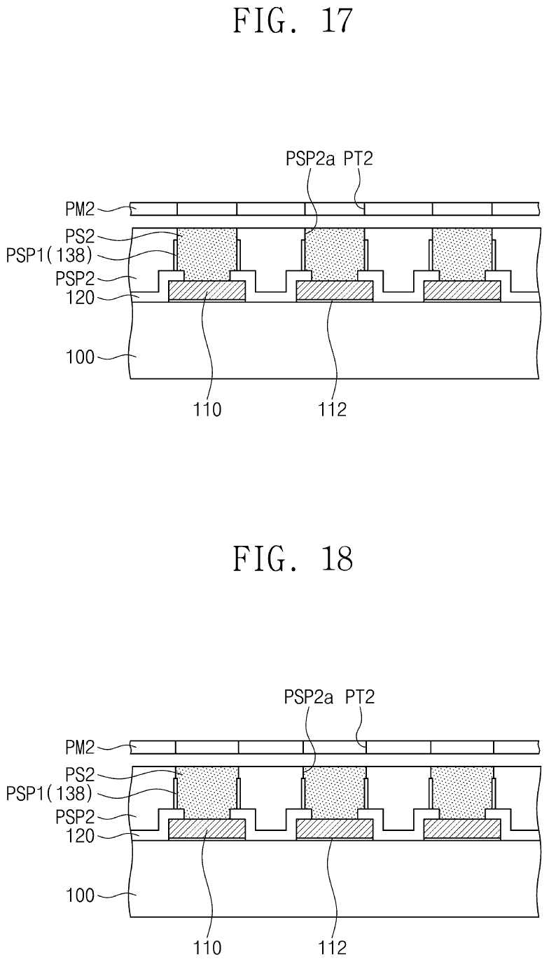

Alternatively, as shown in FIG. 17, the side surface of the portion of the second photosensitive layer PS2 to which the light is irradiated may be aligned with the inner peripheral surface of the first photosensitive patterns PSP1. That is, an interface between the portion of the second photosensitive layer PS2 to which the light is irradiated and the second photosensitive pattern PSP2 may be coplanar with the inner peripheral surface of the first photosensitive patterns PSP1. In this case, the semiconductor package described with reference to FIG. 4 may be manufactured.

Alternatively, as shown in FIG. 18, the side surface of the portion of the second photosensitive layer PS2 to which the light is irradiated may be on the upper surface of the first photosensitive patterns PSP1. That is, an interface between the portion of the second photosensitive layer PS2 to which the light is irradiated and the second photosensitive pattern PSP2 may be between the outer peripheral surface and the inner peripheral surface of the first photosensitive patterns PSP1 when viewed in a plan view. In this case, the semiconductor package described with reference to FIG. 5 may be manufactured. Hereinafter, the description will continue based on the embodiment of FIG. 16.

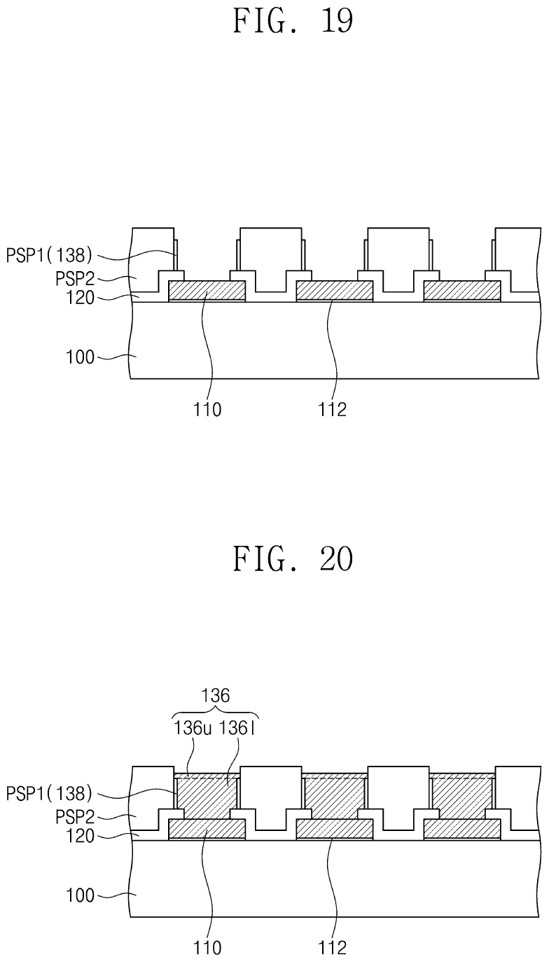

Referring to FIG. 19, the remaining portions of the second photosensitive layer PS2 except for the second photosensitive pattern PSP2 may be removed. Accordingly, second photosensitive patterns PSP2 may remain. The second photosensitive pattern PSP2 may have openings. The first photosensitive patterns PSP1 may be in the openings of the second photosensitive pattern PSP2. In detail, the first photosensitive patterns PSP1 may be on lower inner surfaces of the openings of the second photosensitive pattern PSP2. For example, openings of the second photosensitive pattern PSP2 may expose or extend to an upper surface of the first photosensitive patterns PSP1, an inner wall of the first photosensitive patterns PSP1, and the upper surface of the substrate pads 110. An internal space of the second photosensitive patterns PSP2 may correspond to a space in which conductive posts 136 (refer to FIG. 20) formed in a process to be described later are formed. That is, the second photosensitive patterns PSP may be a sacrificial layer for forming the conductive posts 136.

Referring to FIG. 20, conductive posts 136 may be formed on the substrate pads 110. For example, a plating process may be performed using the substrate pads 110 exposed by the second photosensitive patterns PSP2 and the first photosensitive patterns PSP1 as a seed. Through a plating process, the second photosensitive patterns PSP2 and the first photosensitive patterns PSP1 may be filled with a metal material. Accordingly, conductive posts 136 may be formed in the second photosensitive patterns PSP2 and the first photosensitive patterns PSP1. The plating process may be performed until the upper surfaces of the conductive posts 136 are at a higher level than upper surfaces of the first photosensitive patterns PSP1. A portion of the conductive posts 136 inside the first photosensitive patterns PSP1 may correspond to the lower portion 136l of the conductive posts 136 described with reference to FIG. 1, and another portion of the conductive posts 136 at a level higher than the upper surface of the first photosensitive patterns PSP1 may correspond to the upper portion 136u of the conductive posts 136 described with reference to FIG. 1. A thickness of the upper portion 136u of the conductive posts 136 may be 10% to 20% of a height of the conductive posts 136.

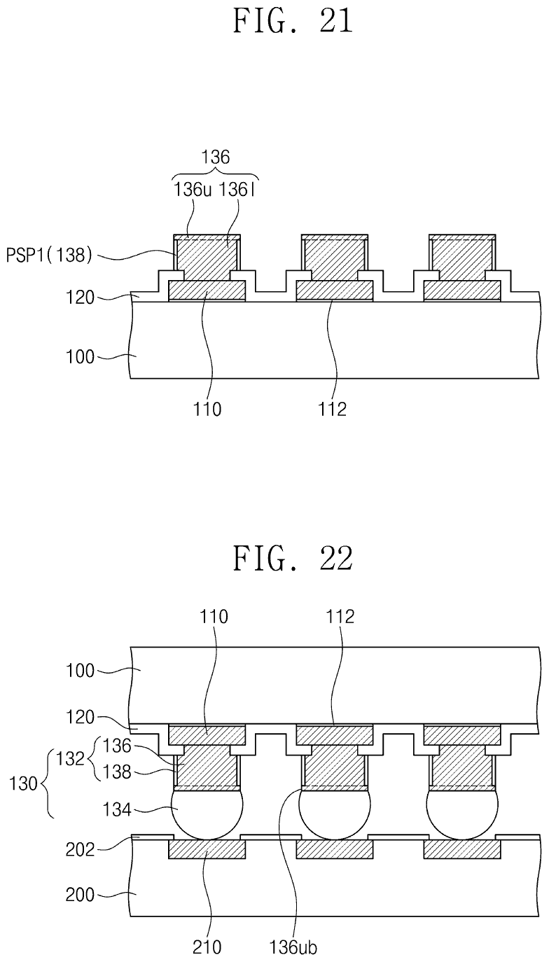

Referring to FIG. 21, the second photosensitive patterns PSP2 may be removed. Accordingly, conductive post structures 132 having a conductive post 136 and an insulating pattern 138 may be formed on the substrate pads 110.

Referring back to FIG. 1, solder bumps 134 may be formed on the conductive post structures 132. The solder bumps 134 may be in contact with upper surfaces of the conductive post structures 132.

With reference to FIG. 22, the mounting of the semiconductor package will be described.

A second substrate 200 may be provided. The second substrate 200 may be a wiring substrate, a semiconductor substrate provided with a semiconductor element, or a semiconductor chip. Second substrate pads 210 may be on an upper surface of the second substrate 200. A second passivation layer 202 may be on the upper surface of the second substrate 200. The second passivation layer 202 may have openings exposing the second substrate pads 210.

The substrate 100 may be on the second substrate 200. In this case, the substrate pads 110, the passivation layer 120, and the bump structures 130 may be on a lower surface of the substrate 100 facing the second substrate 200. The bump structures 130 may face the second substrate pads 210.

The substrate 100 may be provided so that the solder bumps 134 of the bump structures 130 may be in contact with the second substrate pads 210. During a reflow process, the solder bumps 134 may be melted between the substrate pads 110 and the second substrate pads 210 to connect the conductive post structures 132 and the second substrate pads 210. In this case, the molten solder bumps 134 may flow on the outer peripheral surface of a head portion of the conductive post 136. Here, the head portion of the conductive post 136 may correspond to the upper portion 136u of the conductive post 136 described with reference to FIGS. 1 to 5. A pillar of the conductive post 136 may be surrounded by the insulating pattern 138, and the molten solder bumps 134 may not flow onto the outer peripheral surface of the pillar of the conductive post 136 (or the outer peripheral surface of the insulating pattern 138). Here, the pillar of the conductive post 136 may correspond to the lower portion 136l of the conductive post 136 described with reference to FIGS. 1 to 5.

In the semiconductor package according to embodiments of the inventive concept, the lower portion of the conductive post may be surrounded by the insulating pattern that has low wettability with the molten solder bump. During the reflow process for mounting the semiconductor package, side wicking, in which molten solder bumps flow and spread to the lower portion of the conductive post, may not occur. The molten solder bump may not move excessively on the side surface of the conductive post, resulting in the bridge failure connected to another adjacent solder bump. Delamination of the solder bump that may occur when the molten solder bump flows onto the passivation layer, defects due to the air gap, or defects due to the difference in thermal expansion coefficient may not occur. In other words, the method of manufacturing the semiconductor package with fewer defects may be provided, and the semiconductor package manufactured through the method may be provided with improved driving stability.

In addition, the insulating pattern may expose the upper outer peripheral surface of the conductive post. The molten solder bump may surround both the upper surface and the outer peripheral surface of the conductive post, and after the reflow process of the solder bump, the connection terminal strongly coupled to the conductive post may be formed. In other words, the semiconductor package with improved structural stability may be provided.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor package comprising:
a substrate;
a first pad on the substrate; and
a first bump structure on the first pad, wherein the first bump structure includes:
a first conductive post structure on the first pad and connected to an upper surface of the first pad; and
a first solder bump connected to an upper surface of the first conductive post structure, and
wherein the first conductive post structure includes:
a first conductive portion; and
a first insulating pattern on a side surface of a lower portion of the first conductive portion, wherein a side surface of an upper portion of the first conductive portion is free of the first insulating pattern.

2. The semiconductor package of claim 1, wherein a height of the upper portion of the first conductive portion is 10% to 20% of a total height of the first conductive portion.

3. The semiconductor package of claim 1, wherein the upper portion of the first conductive portion extends onto an upper surface of the first insulating pattern.

4. The semiconductor package of claim 3, wherein a side surface of the first insulating pattern and the side surface of the upper portion of the first conductive portion are substantially flat and coplanar.

5. The semiconductor package of claim 1, wherein the side surface of the upper portion of the first conductive portion and the side surface of the lower portion of the first conductive portion are substantially flat and coplanar, and
wherein a side surface of the first insulating pattern forms a step with the side surface of the upper portion of the first conductive portion.

6. The semiconductor package of claim 1, wherein the first bump structure further includes a seed pattern on a lower surface of the first conductive post structure, and
wherein the seed pattern is on a lower surface of the lower portion of the first conductive portion and a lower surface of the first insulating pattern.

7. The semiconductor package of claim 1, wherein a wettability of the first conductive portion with respect to a material forming the first solder bump is greater than a wettability of the first insulating pattern with respect to a material forming the first solder bump.

8. The semiconductor package of claim 7, wherein the first conductive portion includes a metal material, and
wherein the first insulating pattern includes a photosensitive insulating layer.

9. The semiconductor package of claim 1, further comprising:
a second pad on the substrate and spaced apart from the first pad; and
a second bump structure on the second pad,
wherein the second bump structure includes:
a second conductive post structure on the second pad and connected to an upper surface of the second pad; and
a second solder bump connected to an upper surface of the second conductive post structure,
wherein the second conductive post structure includes:
a second conductive portion; and
a second insulating pattern on a side surface of a lower portion of the second conductive portion, wherein a side surface of an upper portion of the second conductive portion is free of the second insulating pattern, and
wherein a thickness of the upper portion of the first conductive portion is different from a thickness of the upper portion of the second conductive portion.

10. The semiconductor package of claim 1, further comprising a passivation layer on the first pad and on the substrate and having an opening exposing the first pad,
wherein the first bump structure is on the passivation layer and connected to the first pad through the opening.

11. The semiconductor package of claim 1, wherein the substrate includes a semiconductor substrate,
wherein an integrated circuit is on an upper surface of the semiconductor substrate, and
wherein the first pad is on the integrated circuit and electrically connected to the integrated circuit.

12. The semiconductor package of claim 1, wherein a portion of the first solder bump extends onto a side surface of the first conductive post structure, and
wherein the first solder bump contacts the side surface of the upper portion of the first conductive portion and is spaced apart from the first insulating pattern.

13. A semiconductor package comprising:
a substrate;
a pad on the substrate;
a passivation layer on the pad and on the substrate and having an opening exposing the pad;
a conductive post structure on the passivation layer and connected to the pad through the opening; and
a solder bump connected to an upper surface of the conductive post structure,
wherein the conductive post structure includes:
a conductive post; and
an insulating pattern on a side surface of the conductive post,
wherein the solder bump contacts an upper surface of the conductive post and a portion of a side surface of the conductive post, and
wherein the insulating pattern is spaced apart from the solder bump.

14. The semiconductor package of claim 13, wherein the conductive post has a lower portion and an upper portion on the lower portion,
wherein the insulating pattern is on the lower portion and a side surface of the upper portion is free of the insulating pattern.

15. The semiconductor package of claim 14, wherein the solder bump is contacts the side surface of the upper portion of the conductive post.

16. The semiconductor package of claim 14, wherein a height of the upper portion of the conductive post is 10% to 20% of a total height of the conductive post.

17. The semiconductor package of claim 14, wherein the upper portion of the conductive post extends onto an upper surface of the insulating pattern, and
wherein a side surface of the insulating pattern and the side surface of the upper portion of the conductive post are substantially flat and coplanar.

18. The semiconductor package of claim 14, wherein the side surface of the upper portion of the conductive post and a side surface of the lower portion of the conductive post are substantially flat and coplanar,
wherein a side surface of the insulating pattern forms a step with the side surface of the upper portion of the conductive post.

19. A method of manufacturing a semiconductor package, the method comprising:
forming a pad on a substrate;
forming a first photosensitive layer on the pad and on the substrate;
performing a first photo process on the first photosensitive layer to form an insulating pattern on the pad, the insulating pattern extending in a direction perpendicular to an upper surface of the pad, and the insulating pattern having a first opening extending through the insulating pattern to the pad;
forming a second photosensitive layer on the pad and on the insulating pattern on the substrate;
performing a second photo process on the second photosensitive layer to form a sacrificial layer, the sacrificial layer having a second opening extending through the sacrificial layer to the first opening;
filling the second opening with a conductive material to form a conductive post;
removing the sacrificial layer; and
providing a solder bump on the conductive post.

20. The method of claim 19, wherein the second opening of the sacrificial layer extends to an upper surface of the insulating pattern, an inner wall of the first opening, and a bottom surface of the first opening, and
wherein the sacrificial layer is on an outer peripheral surface of the insulating pattern.
